(19) United States
(12) Patent Application Publication
(10) Pub. No.: US 2026/0333610 A1
(43) Pub. Date: Oct. 22, 2026

(54) RUGGEDISATION APPARATUS

(71) Applicant: BAE SYSTEMS PLC, London (GB)

(72) Inventor: Alan Leslie Jordan, Barrow in Furness Cumbria (GB)

(73) Assignee: BAE SYSTEMS PLC, London (GB)

(21) Appl. No.: 19/112,093

(22) PCT Filed: Sep. 12, 2023
(86) PCT No.: PCT/GB2023/052350

§ 371 Date: Mar. 14, 2025

(30) Foreign Application Priority Data
Sep. 14, 2022 (GB) 2213430.8

(51) Int. Cl. H05K 7/14; H05K 7/18; H05K 7/20

(52) U.S. Cl. CPC H05K 7/1492; H05K 7/183; H05K 7/205; H05K 7/20709

(57) ABSTRACT

The present invention relates to the ruggedisation of electronic enclosures, particularly to the shock protection of racks, cabinets and enclosures of computers and servers.

There is provided a ruggedised electronic enclosure, comprising a chassis, and a plurality of hardware components, wherein there is a reinforcement spine connected to the chassis and at least one hardware component, to prevent movement of said component during a shock-loading event.

### FIELD

The present invention relates to the ruggedisation of electronic enclosures, particularly to the shock protection of racks, cabinets and enclosures of computers and servers.

### BACKGROUND

Computers, such as servers, personal computers are designed to withstand dropping, when packaged but not large shock forces during normal service life.

### SUMMARY

According to an aspect of the present invention, there is provided a ruggedised electronic enclosure, comprising a chassis and at least one hardware component, further comprising a reinforcement spine connected to the chassis and the at least one hardware component, to prevent movement of said component during a shock-loading event; preferably there are a plurality of hardware components.

The reinforcement spine coupled with the chassis capable of offering protection and/or retention of components during and following a shock event. The shock event typically being greater than the acceleration due to gravity, ie a drop hazard or external event. Typically a sudden deceleration event, or shock loading, such as, for example where shock forces are applied lasting typically less than <50 milliseconds.

The chassis may be a box or container that houses the hardware components, such as the electronic components. The chassis may be typically thin metal sheets, which are fastened together form the container. The chassis may typically have a base, 4 walls, and a lid. Typically the lid or at least one of the walls will be removable to allow access to the hardware components.

The at least one hardware component may be an electronic component, a vulnerable and/or heavy component, such as, for example, processors, network cards, memory, cooling fans, hard drive, memory storage, eg PSUs, PCBs, mounted heatsinks, back-up batteries, cables, connectors etc, the reinforcement spine may preferably retain the at least one heat sink and/or PSU, and power supply. The reinforcement spine may prevent the movement of vulnerable and/or heavy components, and their separation from the chassis and electronic boards.

The reinforcement spine allows the attachment of further structural components, such as reinforcement plates to provide yet further rigidity to the chassis during a shock event where the shock load path is acting on the horizontal plane, which may lie outside of the computer.

The reinforcement spine may further prevent heavy components from leaving the chassis which may lead to power failure or mal-function during and after a shock event. The heavy components may not damage the chassis but may damage surrounding computers/servers, especially within a stack or racked arrangement.

Preferably, at least one said at least one PCB and/or PSU are affixed to the both the chassis and the reinforcement spine.

Preferably, at least one said hard drive and power supply are affixed to the both the chassis and the reinforcement spine.

The reinforcement spine may be attached to the chassis during manufacture or retro-fitted into existing commercial off the shelf (COTS) electronic enclosures. The ability to provide structural integrity through the use of a retro-fit solution to achieve shock compliance allows greater range of electronic enclosures, for example computer systems, to be selected.

The reinforcement spine may comprise at least two sides which are fixedly engaged with the chassis. The at least two sides may be operably fastened by a linkage, which provides rigidity to the at least two sides.

The at least two sides may extend over to form a mounting lip to form part of an upper surface. The at least two sides may comprise the mounting lips which may be operably fastened by the linkage to provide rigidity to the at least two sides.

The at least two sides, may each comprise a lower surface, said lower surface may be fastened to the chassis of the electronic enclosure. The lower surface may be elongate. The lower surface may comprise one of the at least two sides, and a further side. The at least two sides, their respective upper and lower surfaces forming a rigid frame with the linkage.

The linkage may be a tubular rod, bar, slotted panel to allow airflow through the electronic components and chassis. Preferably the linkage may be a plurality of tubular rods to provide both rigidity and reduction of the mass of the reinforcement spine. The use of tubes may also allow for cable management by providing a conduit therethrough.

The reinforcement spine may be made from metal, metal alloys, polymers, fibre reinforced polymer composites.

There may be a further reinforcement spine mounted on top of the reinforcement spine to provide attachment to layered and/or stacked hardware components, particularly heavy internal components. The further reinforcement spine may for example be fastened to a heat sink which may be in thermal contact with electronic components, such as for example they may be located above the processing units.

The reinforcement spine and/or further reinforcement spine may comprise at least one connection element which is mounted thereon, to retain or fasten the at least one item of hardware. The connection element may be reversible such as, for example a clamp, co-operative threads, magnets. The connection element may simply be friction between the linkage and the at least one item of hardware, or clamping between the reinforcement spine and the further reinforcement spine. The reversible connection may also comprise security features, such as locks, interlocks, to control the removal to only authorised users. The connection element may be permanent, such as adhesive bonding, welding, rivets etc.

The connection elements may also be mounted on the mounting lip on the at least two walls of the reinforcement spine.

The reinforcement spine may mitigate the movement of components both inside the electronic enclosure and any neighbouring electronic enclosures, such as for example the movement of components both inside the computer and neighbouring computers, especially when in a rack, cabinet or stacked environment.

As a further means of mitigation the electronic enclosure or computer may comprise a spall liner, to prevent any debris, attachments and fixings ejected from the electronic enclosure during a shock loading event from penetrating adjacent stacked, further electronic enclosures. Debris, attachments and fixings, may be items such as screws, solder, electronic connecters, small electronic components that may be ejected under high shock loadings.

The spall liner may be made from rubberized aramid, high-performance polyethylene or fiberglass. The spall liner may be mounted on the inside of the computer and held in place by the reinforcement spine.

The electronic enclosure may be any type of computer, such as a desktop, laptop, at least one computer or server on a rack, cabinet or stack. The computer is preferably one that is part of a stack or rack of computers/servers, where shock damage caused to one may result in the mal-function or destruction of the rest of the rack, cabinet or stack of computers.

According to a further aspect of the invention there is provided a rack, stack or cabinet electronic system comprising a plurality of servers and or computers, as defined herein, each with a reinforcement spine as defined herein.

### BRIEF DESCRIPTION OF THE FIGURES

Embodiments of the invention will now be described by way of example only with reference to the figures, in which:

FIG. 1 shows prior art computer;

FIG. 2 shows a reinforcement spine according to the invention;

FIG. 3 shows and expanded view of the reinforcement spine in a ruggedised computer;

FIG. 4 shows a further reinforcement spine clamping the heat sink; and

FIG. 5 shows a server rack being separated by reinforcement spines.

### DETAILED DESCRIPTION

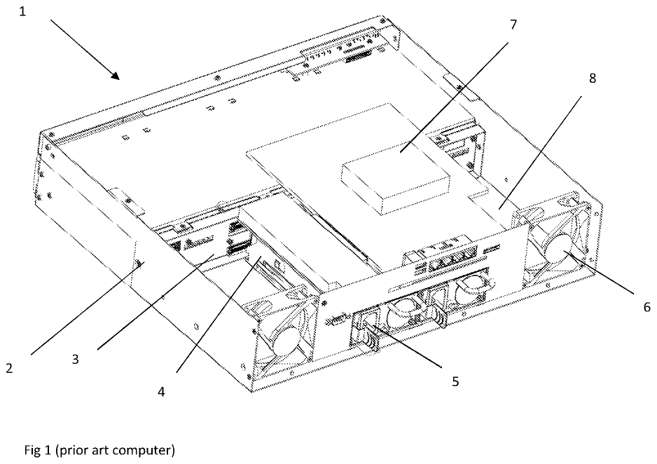

Turning to FIG. 1, there is shown a prior art computer 1, with a chassis 2, housed inside the chassis is a power supply 4 in the form of a transformer, which receives power externally via the socket 5. The chassis further comprises a mother board 8, with a processor which is cooled by a heat sink 7, which is located thereupon. Further cooling is provided by fans 6, to increase airflow around the electronic components. The computer has a storage in the form of hard drives 3.

Turning to FIG. 2 there is provided a reinforcement spine 10, with at least two sides 17, 17a which are capable in use of being attached to a computer chassis. The side 17 has a lower surface 16, and a further side 22, which all three together with the linkage 12 forms a rigid structure to provide reinforcement when attached to the chassis.

The side 17, has a lip 19, which extends at right angles therefrom to form a mounting area for the linkage 12, said linkage 12 is in the form of three tubular rods. The lip 19 also provides a mount for a further reinforcement spine 11, which has at least two sides 18, 18a each of which further comprising a further lip 15. The further lip 15 providing a mounting point for the further linkage 14, in the form of a singular tubular rod.

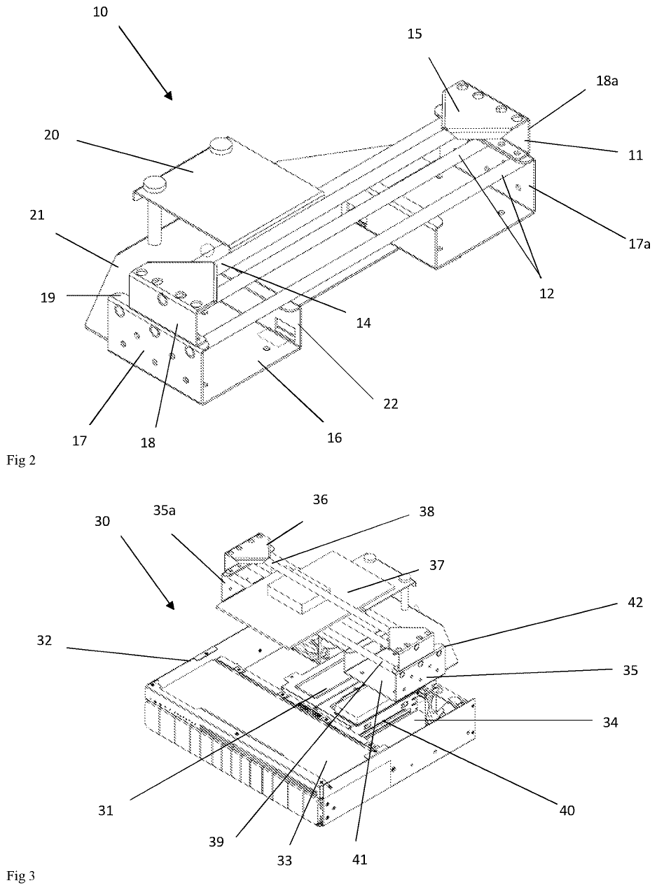

Reinforcement plates 20 and 21 act as extensions from the electronic enclosure which attach to the linkage 12, to retain, in this case, PSUs during a shock event. Especially where the load path of the shock is acting horizontally. Turning to FIG. 3, there is provided a ruggedised computer 30, with a chassis 32, which houses a plurality of hardware components, such as hard drives 33, processors 31, and power supply transformer 40. One of the walls 35, of the at least two side walls 35, 35a and base layer 41 are sized to fit in the cavity 34, adjacent to the power supply transformer 40. The side wall 35 may then be screwed or otherwise affixed to the chassis 32. The at least two walls 35, 35a and their associated base layers 41 are formed into a rigid structure by the linkage 39, to form the reinforcement spine 42. The heat sink 37 which is a heavy bulky metal plate designed to conduct heat away from the processers 31, is retained in place by being clamped between the linkage 39 and the further linkage 38 of the further reinforcement spine 36. In the event of a rapid deceleration or shock event, the heat sink 37 may not be retained by small screws and would damage the processors 31 or be ejected at great velocity and may cause mal-function and/or catastrophic system damage to adjacent computers(see FIG. 5). The reinforcement spine 42 and further reinforcement spine 36 prevent the movement of the heat sink 37, the power supply 40 and provide further rigidity to the chassis 32.

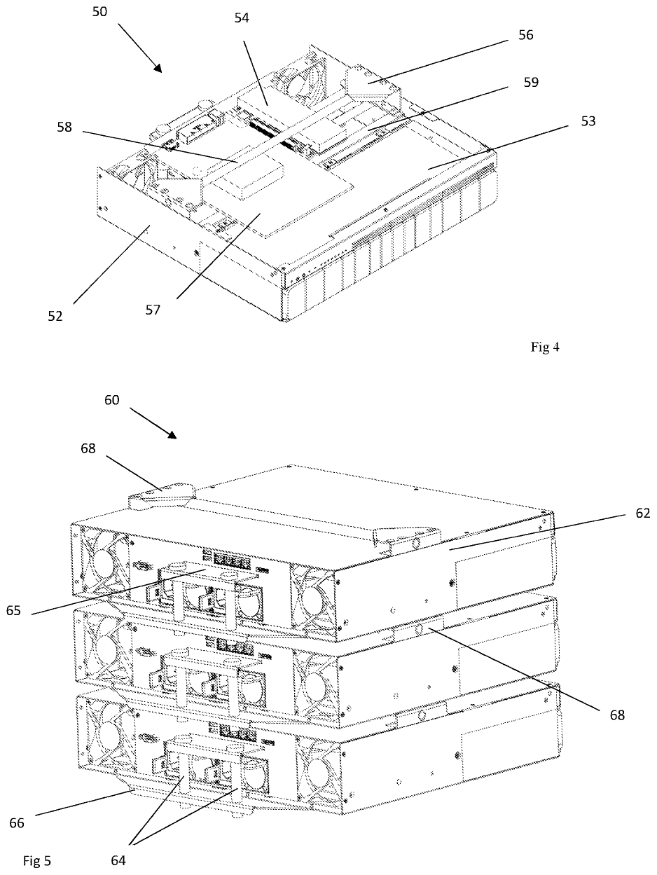

Turning to FIG. 4 there is provided a ruggedised computer 50, with the reinforcement spine 59 being secured to the chassis 52, the further reinforcement spine 56 being fastened to the reinforcement spine 59, the two spines clamping the heat sink 57 and transformer 54 to prevent their movement.

Turning to FIG. 5, there is provided a stack of servers 60, wherein the chassis 62 of each server is separated and connected by an external reinforcement spine 68, to provide yet further rigidity to the stack of servers. Reinforcement plates 65, 66 (as shown in FIG. 2), are a locking feature using vertical locking pins 64 to support PSUs during a shock event where the shock load path is acting on the horizontal plane. The upper plate 65 is rigidly connected to one of the tubular linkages (FIG. 2, item 12). The lower plate 66 can be secured directly to the outside surface of the chassis 60 also increasing the chassis' rigidity.

1. A ruggedised electronic enclosure, comprising:
a chassis;
at least one hardware component; and
a reinforcement spine connected to the chassis and the at least one hardware component, to prevent movement of said component during a shock-loading event.

2. The enclosure, according to claim 1, wherein the at least one hardware component comprises an electronic component.

3. The enclosure according to claim 2, wherein the electronic component is selected from at least one of a processor, a network card, a memory, a hard-drive, a storage, a printed circuit board (PCB), a power supply unit (PSU), a heat sink, or a power supply.

4. The enclosure according to claim 1, wherein the at least one hardware component includes a hard drive and a power supply, which are each affixed to both the chassis and the reinforcement spine.

5. The enclosure according to claim 1, wherein the reinforcement spine is a retrofit insert, which is affixed to the chassis.

6. The enclosure according to claim 1, wherein the reinforcement spine comprises at least two sides which are fixedly engaged with the chassis.

7. The enclosure according to claim 6, wherein the at least two side walls each extend over to form a respective mounting lip theto form part of an upper surface.

8. The enclosure according to claim 7, wherein the at least two sides are operably fastened by a linkage, which provides rigidity to the at least two sides, and/or the respective mounting lips.

9. The enclosure according to claim 8, wherein the linkage is a tubular rod, bar, or slotted panel to allow airflow through the at least one hardware component.

10. The enclosure according to claim 1, wherein there is a connection element which is mounted on the reinforcement spine, to retain the at least one hardware component.

11. The enclosure according-any to claim 1, wherein there is a further reinforcement spine mounted on top of the reinforcement spine.

12. The enclosure according to claim 1, comprising a spall liner.

13. The enclosure according to claim 1, wherein the electronic enclosure is at least one server or computer.

14. A rack, stack or cabinet electronic system comprising the at least one server or computer according to claim 13.

15. The system according to claim 14, wherein located between a first server or computer of the system and a second server or computer of the system is an external reinforcement spine to prevent the separation of said first and second servers or computers.

16. A ruggedised electronic enclosure, comprising:
a chassis;
at least one hardware component; and
a reinforcement spine connected to the chassis and the at least one hardware component, to prevent movement of said component during a shock-loading event, wherein the reinforcement spine comprises at least two sides which are fixedly engaged with the chassis, and wherein the at least two sides are operably fastened by a linkage, which provides rigidity to the at least two sides, and/or the respective mounting lips.

17. The enclosure, according to claim 16, wherein the at least one hardware component comprises at least one of a processor, a network card, a memory, a hard-drive, a storage, a printed circuit board (PCB), a power supply unit (PSU), a heat sink, and a power supply.

18. The enclosure according to claim 16, wherein the at least one hardware component includes a hard drive and a power supply, which are each affixed to both the chassis and the reinforcement spine.

19. The enclosure according to claim 16, wherein the linkage is a tubular rod, bar, or slotted panel to allow airflow through the at least one hardware component.

20. A ruggedised electronic enclosure, comprising:
a chassis;
at least one hardware component;
a first reinforcement spine connected to the chassis and the at least one hardware component, to prevent movement of said component during a shock-loading event, wherein the reinforcement spine comprises at least two sides which are fixedly engaged with the chassis, and wherein the at least two sides are operably fastened by a linkage, which provides rigidity to the at least two sides, and/or the respective mounting lips;
a further reinforcement spine mounted on top of the first reinforcement spine; and
a connection element mounted on the first or second reinforcement spine, to retain the at least one hardware component.
